(19) United States
(12) Patent Application Publication
(10) Pub. No.: US 2005/0076828 A1
(43) Pub. Date: Apr. 14, 2005

(54) Process for fabrication of III nitride-based compound semiconductors

(75) Inventors: Tetsuya Taki, Aichi-ken (JP); Yasuhisa Ushida, Aichi-ken (JP); Kazuki Nishijima, Aichi-ken (JP)

Correspondence Address: MCGINN & GIBB, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 10/924,260

(22) Filed: Aug. 24, 2004

(30) Foreign Application Priority Data
Aug. 26, 2003 (JP) 2003-300955

(51) Int. Cl. C30B 23/00; C30B 25/00; C30B 28/12; C30B 28/14

(52) U.S. Cl. 117/89

(57) ABSTRACT

A process for the fabrication of a III nitride-based compound semiconductor includes a first crystal growth step for growing a semiconductor layer A made of a III nitride-based compound semiconductor on a crystal growth surface, and a second crystal growth step for growing a semiconductor layer B made of a III nitride-based compound semiconductor on the semiconductor layer A in which a lateral crystal growth rate of the semiconductor layer A in the first crystal growth step is lower than a lateral crystal growth rate of the semiconductor layer B in the second crystal growth step.

The present application is based on Japanese patent application No. 2003-300955, the entire contents of which are incorporated herein by reference.

### BACKGROUND OF THE INVENTION

1. Field of the Invention

The present invention relates to a process for the fabrication of good III nitride-based compound semiconductors by crystal growth of a semiconductor.

The process of the fabrication according to the present invention is very useful not only for the fabrication of semiconductor light-emitting devices and semiconductor light-receiving devices, but also for semiconductor substrates of a variety of electronic devices including a pressure sensor and the like.

2. Description of the Related Art

As literary documents for disclosing a crystal growth method wherein a convexoconcave area is formed on a crystal growth substrate or a crystal growth surface of a semiconductor crystal, and onto which crystal growth of a semiconductor crystal to be laminated is conducted with low dislocation, there are, for example, the following patent literary documents 1 to 4 and the like:
1. Japanese Patent application laid-open No. 2000-124500.
2. Japanese Patent application laid-open No. 2002-241192.
3. Japanese Patent application laid-open No. 2002-164296.
4. Japanese Patent application laid-open No. 2002-280609.

However, in the crystal growth method appeared in these patent literary documents 1 to 4, it is necessary for forming mechanically a convexoconcave area on a crystal growth substrate or a crystal growth surface of a semiconductor crystal as described above. Thus, considerable time and effort for designing and working figures of a crystal growth surface for forming a convexoconcave area are required in these conventional processes of the fabrication. In other words, the above-described prior art does not necessarily provide desirable crystal growth method in view of production efficiency in a product development process or a production line.

### SUMMARY OF THE INVENTION

Accordingly, the present invention has been made for solving the above-described problems and an object of which is to suppress effectively a dislocation density or a pits density per unit area of a target semiconductor crystal.

A further object of the present invention is to provide a crystal growth method wherein crystal growth of a target semiconductor crystal is promoted with low dislocation which is simpler and more efficient than a conventional method.

It is, however, to be noted a sufficient result is in that any individual object of those described above is individually attained by at least any individual one means of those contained in the present invention, but any individual invention according to this application does not necessarily ensure that there is a means by which all the problems described above is solved at the same time.

In order to solve the above-described problems, the following means are effective.

A first means of the present invention corresponds to a process for the fabrication of a III nitride-based compound semiconductor comprises a first crystal growth step for growing a semiconductor layer A made of a III nitride-based compound semiconductor on a crystal growth surface provided by a substrate or a buffer layer by supplying a III element material gas at a rate of a_{III} [μmol/min] per unit time and supplying a V element material gas at a rate of a_{V} [μmol/min] per unit time; and a second crystal growth step for growing a semiconductor layer B made of a III nitride-based compound semiconductor on the semiconductor layer A by supplying a III element material gas at a rate of b_{III} [μmol/min] per unit time and supplying a V element material gas at a rate of b_{V} [μmol/min] per unit time; wherein a ratio R_{A} (≡a_{V}/a_{III}) is lower than a ratio R_{B} (≡b_{V}/b_{III}), whereby a lateral crystal growth rate V_{LA} of the semiconductor layer A in the first crystal growth step is lower than a lateral crystal growth rate V_{LB} of the semiconductor layer B in the second crystal growth step.

It is desirable that a difference between the crystal growth rate V_{LA} and the crystal growth rate V_{LB} is remarkable as much as possible so far as any amorphous area is formed in respective layers of the semiconductor layer A and the semiconductor layer B.

It is, however, to be noted that the term “III nitride-based compound semiconductors” used herein generally include semiconductors represented by a general formula of secondary, tertiary, and quaternary “Al_{1-x-y}Ga_{y}InₓN; 0≦x≦1, 0≦y≦1, 0<1−x−y≦1” with an arbitrary mixed crystal ratio, and further, semiconductors to which p- or n-type impurities are added are also within a category of “the III nitride-based compound semiconductors”.

Moreover, semiconductors and the like wherein at least a part of the above-described III elements (Al, Ga, and In) is substituted by boron (B), thallium (Tl) or the like, or at least a part of nitrogen (N) is substituted by phosphorus (P), arsenic (As), antimony (Sb), bismuth (Bi) or the like are also included in the category of “the III nitride-based compound semiconductors”.

As the above-described p-type impurities (acceptors), well-known p-type impurities, for example, magnesium (Mg), calcium (Ca) and the like may be added.

On one hand, as the above-described n-type impurities (donors), well-known n-type impurities, for example, silicon (Si), sulfur (S), selenium (Se), tellurium (Te), germanium (Ge) and the like may be added.

Furthermore, addition of these impurities (acceptors or donors) may be effected by adding two or more elements at the same time, or adding both the types (p- and n-types) of impurities at the same time.

A well-known or an optional material may be applied as a crystal growth substrate. For instance, a bulk crystal made of AlGaN, a bulk crystal made of GaN or the like may be applied as the above-described substrate. In case of applying the above-described III nitride-based compound semiconductors as substrates, it is not required necessarily to form a buffer layer.

A heterosubstrate different from a III nitride-based compound semiconductor may also be used. In this case, a buffer layer is usually provided in order to moderate adverse influences due to a difference in lattice constants. As the heterosubstrates, well-known substrates such as sapphire, silicon, and silicon carbide substrates are applicable.

In addition, it is not necessarily required that the semiconductor layer A and the semiconductor layer B are prepared from III nitride-based compound semiconductors having the same composition ratio.

MOVPE, HVPE, MBE, or the like method may be applied as a crystal growth method for crystal-growing a III nitride-based compound semiconductor (each semiconductor layer) on a semiconductor substrate.

A second means of the present invention corresponds to the process for the fabrication of a III nitride-based compound semiconductor in the above-described first means wherein the ratio R_{A} and the ratio R_{B} satisfy a condition R_{A}<900<R_{B}.

A more preferred range of the ratio R_{B} is 1000 or more.

A third means of the present invention corresponds to the process for the fabrication of a III nitride-based compound semiconductor in the above-described first or second means wherein the ratio R_{A} satisfies a condition 100<R_{A}<800.

A fourth means of the present invention corresponds to the process for the fabrication of a III nitride-based compound semiconductor in any one of the first, second, and third means wherein a crystal growth temperature T_{B} of the semiconductor layer B in the second crystal growth step is established at a value higher than a crystal growth temperature T_{A} of the semiconductor layer A in the first crystal growth step.

Furthermore, a fifth means of the present invention corresponds to the process for the fabrication of a III nitride-based compound semiconductor in the above-described fourth means wherein the crystal growth temperature T_{A} and the crystal growth temperature T_{B} are to be T_{A} [° C.]≦1000 [° C.]≦T_{B} [° C.]

Still further, a sixth means of the present invention corresponds to the process for the fabrication of a III nitride-based compound semiconductor in any one of the above-described first through fifth means wherein a film thickness of the semiconductor layer A is made to be 0.3 μm or more.

It is more preferred that a film thickness of the semiconductor layer A to be laminated is 0.5 μm or more.

Moreover, a seventh means of the present invention corresponds to the process for the fabrication of a III nitride-based compound semiconductor in any one of the above-described first through sixth means wherein a film thickness of the semiconductor layer A is made to be 1 μm or less.

Besides, an eighth means of the present invention corresponds to the process for the fabrication of a III nitride-based compound semiconductor in any one of the above-described first through seventh means comprises further a third crystal growth step for growing a semiconductor layer C made of a III nitride-based compound semiconductor on the semiconductor layer B wherein a ratio R_{C} (=c_{V}/c_{III}) of a feed rate c_{V} [μmol/min] per unit time of a V element material gas with respect to a feed rate c_{III} [μmol/min] per unit time of a III element material gas in the third crystal growth step is established to satisfy a condition R_{A}<R_{C}≦R_{B}.

It is, however, to be noted that the above-described semiconductor layers B and C are not necessarily formed from III nitride-based compound semiconductors having the same composition ratio.

In addition, a ninth means of the present invention corresponds to the process for the fabrication of a III nitride-based compound semiconductor in the above-described eighth means wherein the ratio R_{B} and the ratio R_{C} are established to satisfy a condition R_{C}≦1200≦R_{B}.

Moreover, a tenth means of the present invention corresponds to a process for the fabrication of a III nitride-based compound semiconductor comprises a first crystal growth step for growing a first layer of a III nitride-based compound semiconductor at a first lateral crystal growth rate; and a second crystal growth step for growing second layer of a III nitride-based compound semiconductor on the first layer at a second lateral crystal growth rate which is lower than the first lateral crystal growth rate.

An eleventh means of the present invention corresponds to the process for the fabrication of a III nitride-based compound semiconductor in the above-described tenth means comprises further a third crystal growth step for growing a third layer of a III nitride-based compound semiconductor on the second layer at a third lateral crystal growth rate which is higher than the first lateral crystal growth rate, but which is equal to or lower than the second lateral crystal growth rate.

A twelfth means of the present invention corresponds to a process for the fabrication of a III nitride-based compound semiconductor comprises a first crystal growth step for growing a first layer of a III nitride-based compound semiconductor having a convexoconcave surface on a substrate or a buffer layer, the convexoconcave surface being magnified in accordance with a convexoconcave surface of the substrate or the buffer layer; and a second crystal growth step for growing a second layer of a III nitride-based compound semiconductor on the first layer.

According to the above-described means of the present invention, the problems mentioned above can be effectively and reasonably solved.

Advantageous effects obtained by the above enumerated means of the present invention are as follows.

Namely, in accordance with the first means of the present invention, a crystal growth of the semiconductor layer A in a lateral direction is more suppressed than that of the semiconductor layer B. Accordingly, the crystal growth of the semiconductor layer A is relatively promoted in a vertical direction (growth axial direction). FIGS. 1A and 1B are schematic sectional views each illustrating an appearance of such crystal growth as mentioned above. In such crystal growth process (first crystal growth step), a slight convexoconcave area in a crystal growth surface s provided by the substrate 1 or the buffer layer 2 is magnified intensively along its vertical direction on the upper surface of the semiconductor layer A as shown by a magnified and waved convexoconcave surface S in FIGS. 1A and 1B, respectively. Even in a case where an original crystal growth surface s is almost flat, it is possible to obtain a magnified and waved convexoconcave surface (area) S on the upper surface of the semiconductor layer A sufficient to function a lateral growth action of the semiconductor layer B which is later to be laminated by optimizing either the ratio R_{A} (≡a_{V}/a_{III}; hereinafter referred optionally to as V/III ratio), or the crystal growth temperature T_{A} etc.

Thus, there is no need of applying a mechanical shaping step with respect to the crystal growth surface s of a crystal growth substrate (the substrate 1) or a semiconductor crystal (the buffer layer 2) in the fabrication processes of the present invention unlike the conventional ELO growth method as mentioned above.

More specifically, the semiconductor layer B exhibiting a comparatively high growth rate in its lateral direction is laminated on the semiconductor layer A on the top of which a sufficiently waved convexoconcave area S has been formed in the following second crystal growth step. Accordingly, concave portions formed on the top surface of the semiconductor layer A are filled up satisfactorily as a result of a lateral growth of the semiconductor layer B, and at the same time, a crystal growth of the semiconductor layer B with low dislocation is promoted (FIG. 1B).

As a consequence, the semiconductor layer B can be satisfactorily crystal-grown without requiring any mechanical shaping with respect to a crystal growth surface of a crystal growth substrate or a semiconductor crystal due to the above-described functions. Hence, a III nitride-based compound semiconductor (semiconductor layer B) having a satisfactory crystallinity can be obtained by a manner which is simpler than a conventional one in accordance with the first means of the present invention. Accordingly, a productivity of semiconductor device can be remarkably elevated according to the present invention.

In accordance with the present invention, since III nitride-based compound semiconductors of a high quality having a good crystallinity can be fabricated, such an advantage that a device being driven with a low drive voltage, and having high luminance and electrostatic breakdown voltage is obtained in case of, for example, fabricating LEDs.

Furthermore, it is desired that a difference between a lateral crystal growth rate V_{LA} and a crystal growth rate V_{LB} in each layer of the semiconductor layers A and B is remarkable as much as possible so far as no amorphous area appears. In this respect, such difference can be effectively achieved in accordance with the second means of the present invention.

It is more preferred that a ratio R_{B} is within a range of 1000 or more. When such a value is small, it is difficult to ensure sufficiently the above-described difference, while although a large value is desirable in view of quality, there is a saturation point, so that an excessive value brings about useless consumption of materials, resulting in an unsuitable production cost due to such excessive value of the ratio R_{B}.

Particularly, according to the third means of the present invention, the lateral crystal growth rate V_{LA} of the semiconductor layer A can be effectively suppressed while assuring a crystallinity of the semiconductor layer A.

Moreover, according to the fourth, fifth or the like means, a difference between the crystal growth rate V_{LA} and the crystal growth rate V_{LB} can be effectively obtained also.

As to an action principle, a more preferable setting standard and the like relating to such temperature setting as mentioned above, crystal growth techniques described, for example, in Japanese patent application laid-open Nos. 2000-357820, 2003-68662, or 11-220169 may be referred to.

Specific and optimum crystal growth conditions relevant to a V/III ratio, a crystal growth temperature and the like will be fully exemplified in the undermentioned examples.

Furthermore, according to the sixth means of the present invention, a convexoconcave area S formed on the top of the semiconductor layer A is intensified necessarily and sufficiently in a vertical direction. As a result, a room wherein the semiconductor layer B grows laterally can be sufficiently ensured. Thus, crystal growth of the semiconductor layer B with low dislocation is promoted to obtain a III nitride-based compound semiconductor (semiconductor layer B) in accordance with the sixth means of the present invention.

An appearance of a stress acting between a substrate and a III nitride-based compound semiconductor (the semiconductor layer A, the semiconductor layer B) can be effectively suppressed according to the seventh means of the present invention in the case where a heterosubstrate such as a sapphire substrate is used. In case of applying a heterosubstrate, it is more preferred that a film thickness of the semiconductor layer A is 0.7 μm or less.

As a result of such setting of conditions, even in the case where a heterosubstrate is used, a frequency of occurrence of warps, dislocations, cracks and the like can be effectively suppressed.

According to the eighth means of the present invention, since the most ideal ratio between a lateral growth action and a vertical growth action can be attained, a III nitride-based compound semiconductor (the semiconductor layer C) of a high crystal quality can be obtained.

A reason to be R_{A}<R_{C} is in that preferable is to suppress a lateral crystal growth rate V_{LA} as much as possible in the semiconductor layer A. On the other hand, a reason to be R_{C}≦R_{B} is in that it is required to attain a sufficient lateral crystal growth rate V_{LB} in the semiconductor layer B. In other words, an intermediate setting of conditions between the first crystal growth wherein a vertical crystal growth action should be more intensified and the second crystal growth wherein a lateral crystal growth action should be more intensified is desirable in a crystal growth process of the semiconductor layer C. As a consequence, the vertical and lateral growth actions are moderately balanced, so that a III nitride-based compound semiconductor (the semiconductor layer C) having a flat surface and a high crystal quality can be obtained.

In accordance with the setting conditions as mentioned above, for example, an LED device which can be driven by a low drive voltage (Vf), and has high luminance and electrostatic breakdown voltage can be fabricated. For instance, when a value of the ratio R_{C} is set out at a value somewhat lower than that of the ratio R_{B} so as to be R_{C}≦R_{B}, it is confirmed experimentally that such arrangement exhibits a remarkable effect for particularly suppressing a drive voltage of a light-emitting device.

Particularly, when the semiconductor layers A, B, and C of the present invention made of gallium nitride (GaN) are sequentially laminated on a sapphire substrate through a buffer layer, an optimum boundary value Rₜₕ between R_{C} and R_{B} is around 1200 (the ninth means of the present invention).

Of course, the optimum boundary value Rₜₕ (R_{C}≦Rₜₕ≦R_{B}) depends upon a mixed crystal ratio of the III nitride-based compound semiconductors (the semiconductor layers B, C) to be laminated, or an amount of an impurity to be added/replaced. In this respect, a value of about 1000 or more is suitable.

### BRIEF DESCRIPTION OF THE DRAWINGS

The present invention will be explained in more detail in conjunction with appended drawings, wherein:

FIG. 1A is a schematic sectional view of a semiconductor layer A wherein an appearance of crystal growth is illustrated;

FIG. 1B is a schematic sectional view of a semiconductor layer B wherein an appearance of crystal growth is illustrated;

FIG. 2 is a sectional view showing a semiconductor light-emitting device 100;

FIG. 3 is a graphical representation indicating photoluminescence of semiconductor layers; and

FIG. 4 is a table wherein advantageous effects of the present invention are specifically exemplified.

### DESCRIPTION OF THE PREFERRED EMBODIMENTS

The present invention will be described on the basis of specific examples hereinafter.

It is, however, to be noted that the embodiments embodying the present invention are not limited to the individual detailed manners described below.

### EXAMPLE 1

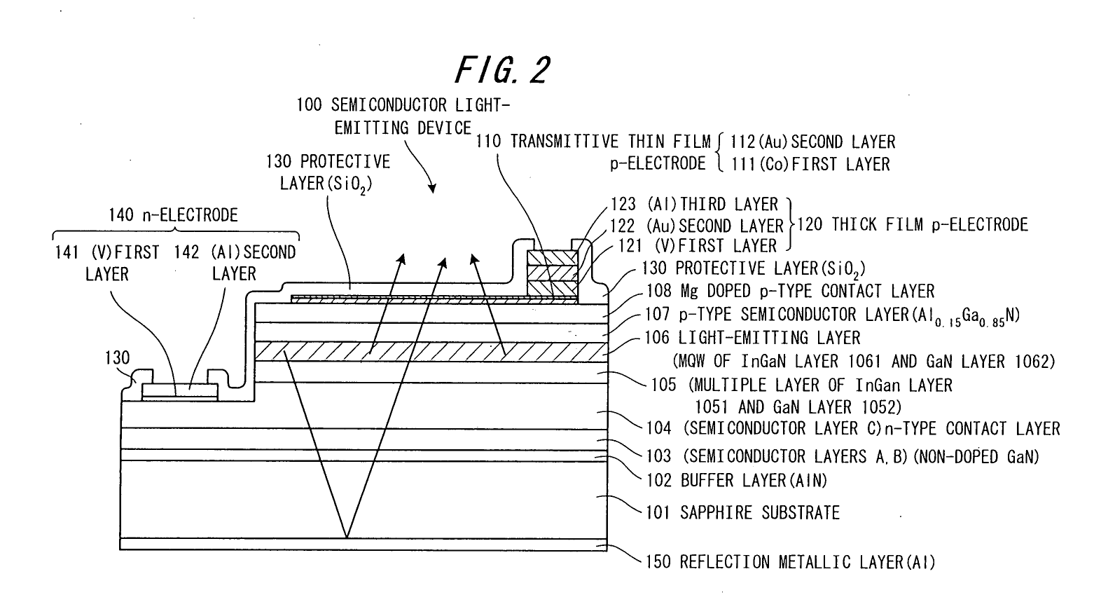

FIG. 2 is a schematic sectional view illustrating a semiconductor light-emitting device 100 according to an example of the present invention which is composed of a buffer layer 102 made of aluminum nitride (AlN) having a film thickness of about 30 nm formed on a sapphire substrate 101 having about 300 μm thickness, a semiconductor layer 103 made of a non-doped GaN having about 700 nm film thickness formed on the buffer layer 102, and an n-type contact layer 104 (high carrier concentration n⁺ layer) made of silicon (Si) 1×10¹⁸/cm³ doped GaN having about 4 μm film thickness formed on the semiconductor layer 103. In this case, the semiconductor layer 103 made of the non-doped GaN has a two-layered structure composed of the above-mentioned semiconductor layer A having 500 nm film thickness and the above-mentioned semiconductor layer B having 200 nm film thickness. In this case, of course, the semiconductor layer A is laminated prior to a formation of the semiconductor layer B by crystal growth (the first crystal growth step).

The n-type contact layer 104 (high carrier concentration n+ layer) made of the silicon (Si) 1×10¹⁸/cm³ doped GaN having 4 μm film thickness corresponds to the above-mentioned semiconductor layer C.

Furthermore, a multiple layer (a layer for improving electrostatic breakdown voltage) 105 prepared by laminating five pairs of a non-doped In_{0.03}Ga_{0.97}N layer 1051 having 3 nm film thickness and a non-doped GaN layer 1052 having 20 nm film thickness is formed on the n-type contact layer 104 (semiconductor layer C).

A light-emitting layer 106 having a multi-quantum-well (MQW) structure prepared by laminating three pairs of a well layer 1061 made of non-doped In_{0.2}Ga_{0.8}N having 3 nm film thickness and a barrier layer 1062 made of non-doped GaN having 20 nm film thickness is formed on the multiple layer 105.

Moreover, a p-type semiconductor layer 107 made of Mg 2×10¹⁹/cm³ doped p-type Al_{0.15}Ga_{0.85}N having 25 nm film thickness is formed on the light-emitting layer 106, and a p-type contact layer 108 made of Mg 8×10¹⁹/cm³ p-type GaN having 100 nm film thickness is laminated on the p-type semiconductor layer 107.

Besides, a transmittive thin film p-electrode 110 obtained by metal deposition is formed on the p-type contact layer 108, while an n-electrode 140 is formed on the n-type contact layer 104. The transmittive thin film p-electrode 110 is composed of a first layer 111 made of cobalt (Co) having about 1.5 nm film thickness and joined directly to the p-type contact layer 108, and a second layer 112 made of gold (Au) having about 6 nm film thickness and joined to the cobalt film.

A thick film p-electrode 120 is prepared by laminating sequentially a first layer 121 made of vanadium (V) having about 18 nm film thickness, a second layer 122 made of gold (Au) having about 15 nm film thickness, and a third layer 123 made of aluminum (Al) having about 10 nm film thickness on the transmittive thin film p-electrode 110.

The n-electrode 140 having a multilayer structure is prepared by laminating a first layer 141 made of vanadium (V) having about 18 nm film thickness, and a second layer 142 made of aluminum (Al) having about 100 nm film thickness on a partially exposed area of the n-type contact layer 104.

A protective layer 130 made of a SiO₂ film is formed on the uppermost part of the semiconductor light-emitting device 100.

A reflection metallic layer 150 made of aluminum (Al) having about 500 nm film thickness is uniformly formed on the lowermost part of the opposite side (outer side) of the light-emitting device 100 corresponding to the bottom surface of the sapphire substrate 101 by means of metal deposition.

It is to be noted that the reflection metallic layer 150 may be prepared from nitrides such as TiN, and HfN in addition to metals such as Rh, Ti, and W.

In the following, a process for the fabrication of the LED (semiconductor light-emitting device 100) will be described.

The above-described semiconductor light-emitting device 100 is fabricated through a vapor phase growth in accordance with metal organic vapor phase epitaxy (MOVPE) method. Gases used are ammonia (NH₃), a carrier gas (H₂, N₂), trimethyl gallium (Ga(CH₃)₃) (hereinafter referred to as “TMG”), trimethyl aluminum (Al(CH₃)₃) (hereinafter referred to as “TMA”)), trimethyl indium (In(CH₃)₃) (hereinafter referred to as “TMA”), silane (SiH₄), and biscyclopentadienyl magnesium (Mg(C₅H₅)₂) (hereinafter referred to as “CP₂Mg”).

First, the single crystal sapphire substrate 101 washed by means of organic cleaning and wherein a-plane is its principal plane is mounted on a susceptor placed in a reaction chamber of an MOVPE device. Then, the substrate 101 is baked at a temperature of 1150° C. while allowing H₂ to flow into the reaction chamber under normal pressure.

Thereafter, a temperature of the substrate 101 is lowered to 400° C., and H₂, NH₃, and TMA are supplied to form the AlN buffer layer 102 having about 30 nm film thickness.

(1) The First Crystal Growth Step (: Crystal Growth of the Semiconductor Layer 103)

Then, a temperature of the substrate 101 is elevated to 1100° C., and H₂, NH₃, and TMG are supplied to form the above-mentioned semiconductor layer A made of GaN and having a film thickness of about 500 nm. In this case, a feed rate a_{III} of a III element gas (TMG) and a feed rate of a_{V} of a V element gas (NH₃) are that described in the following crystal growth condition 1.

[Crystal Growth Condition 1]

Gas feed rate a_{III}: 570 [μmol/min]
Gas feed rate a_{V}: 131100 [μmol/min]
V/III ratio R_{A}: 230 (≡a_{V}/a_{III})

(2) The Second Crystal Growth Step (: Crystal Growth of the Semiconductor Layer 103)

Then, H₂, NH₃, and TMG are supplied while maintaining a temperature of the substrate 101 to form the above-mentioned semiconductor layer B made of GaN and having about 200 nm film thickness. In this case, a feed rate b_{III} of a III element gas (TMG) and a feed rate of b_{V} of a V element gas (NH₃) are that described in the following crystal growth condition 2.

[Crystal Growth Condition 2]

Gas feed rate b_{III}: 570 [μmol/min]
Gas feed rate b_{V}: 672600 [μmol/min]
V/III ratio R_{B}: 1180 (≡b_{V}/b_{III})

(3) The Third crystal Growth Step (: Crystal Growth of the N-Type Contact Layer 104)

Then, H₂, NH₃, TMG, and silane are supplied while maintaining a temperature of the substrate 101 to form the n-type contact layer 104 (the above-mentioned semiconductor layer C) made of silicon (Si) doped GaN and having about 4.0 film thickness and 2×10¹⁸ cm⁻³ electron concentration. In this case, a feed rate c_{III} of a III element gas (TMG) and a feed rate of c_{V} of a V element gas (NH₃) are that described in the following crystal growth condition 3.

[Crystal Growth Condition 3]

Gas feed rate c_{III}: 570 [μmol/min]
Gas feed rate c_{V}: 672600 [μmol/min]
V/III ratio R_{C}: 1180 (≡C_{V}/C_{III})

Thereafter, the respective semiconductor layers 105, 106, 107, and 108 are sequentially laminated by crystal growth as follows.

(Crystal Growth of the Multiple Layer 105)

The multiple layer 105 performing an action of improvement for electrostatic breakdown voltage is prepared by laminating five pairs of the layer 1051 made of non-doped In_{0.03}Ga_{0.97}N and having 3 nm film thickness, and the layer 1052 made of non-doped GaN having 20 nm film thickness.

In this case, a lamination of the layer 1051 is conducted in such that a crystal growth temperature of the layer 1051 is set at 850° C., and N₂, NH₃, TMG, and TMI are supplied.

On one hand, a lamination of the layer 1052 is conducted in such that a crystal growth temperature of the layer 1052 is set at 850° C., and N₂, NH₃, and TMG are supplied.

(Crystal Growth of the Light-Emitting Layer 106)

The light-emitting layer 106 having a multi-quantum-well structure is prepared by laminating three pairs of the well layer 1061 made of non-doped In_{0.2}Ga_{0.8}N and having 3 nm film thickness and the barrier layer 1062 made of non-doped GaN and having 20 nm film thickness.

In this case, a lamination of the layer 1061 is conducted in such that a crystal growth temperature of the layer 1061 is set at 730° C., and N₂, NH₃, TMG, and TMI are supplied.

Furthermore, a lamination of the layer 1062 is conducted in such that a crystal growth temperature of the layer 1062 is set at 850° C., and N₂, NH₃, and TMG are supplied.

(Crystal Growth of P-Type Semiconductor Layer 107)

Thereafter, a temperature of the substrate 101 is elevated to 1000° C., a carrier gas which has been used is replaced by H₂, and TMG, TMA, and CP₂Mg are supplied to form the p-type semiconductor layer 107 made of 5×10¹⁹/cm³ concentration magnesium (Mg) doped p-type Al_{0.15}Ga_{0.85}N.

(Crystal Growth of the P-Type Contact Layer 108)

Finally, a temperature of the substrate 101 is kept at 1000° C., and NH₃, TMG and CP₂Mg are supplied with the use of a carrier gas H₂ to form the p-type contact layer 108 made of 5×10¹⁹/cm³ concentration Mg doped p-type GaN and having about 85 nm film thickness.

The steps mentioned above are crystal growth steps for respective semiconductor layers each made of a III nitride-based compound semiconductor.

After the above crystal growth steps, an etching mask is formed on the p-type contact layer 108, the mask covering a predetermined region is removed, and each part, which is not covered with the mask) of the p-type contact layer 108, the p-type semiconductor layer 107, the light-emitting layer 106, the multiple layer 105 (a layer for improving electrostatic breakdown voltage), and the n-type contact layer 104 is etched with a gas containing chlorine in accordance with reactive ion etching to expose a surface of the n-type contact layer 104.

Thereafter, the negative electrode 140 to be joined to the n-type contact layer 104, and the transmittive thin film positive electrode 110 to be joined to the p-type contact layer 108 are formed in accordance with the following procedures.

(1) In a metallizing apparatus, the materials in process are highly evacuated at an order of 10⁻⁴ Pa or less, a Co film having about 1.5 nm thickness is substantially homogeneously formed on a surface of the materials, and a second layer 112 of the thin film positive electrode made of Au and having about 6 nm film thickness is formed on a first layer 111, prepared from the Co, of the thin film positive electrode.

(2) Then, a photoresist is homogeneously applied to a surface of the resulting materials, and a part of the photoresist, which has been applied to a region other than that where the transmittive thin film positive electrode 110 is to be formed by lamination with respect to the p-type contact layer 108 in accordance with photolithography, is removed.

(3) Then, the photoresist is removed after removing the Co and Au exposed by etching, and the transmittive thin film positive electrode 110 is formed on the p-type contact layer 108.

(4) Thereafter, a photoresist is applied to the resulting materials, a window is formed on a predetermined region on an exposed surface of the n-type contact layer 104 in accordance with photolithography, the materials in process are highly evacuated at an order of 10⁻⁴ Pa or less, and then, a vanadium (V) layer 141 having about 17.5 nm film thickness and an aluminum (Al) layer 142 having about 1.8 μm film thickness are sequentially deposited. Then, the photoresist is removed. As a consequence, the negative electrode 140 is formed on an exposed surface of the n-type contact layer 104.

In order to form further the thick film positive electrode 120 on the transmittive thin film positive electrode 110 formed in accordance with the above-described steps, a photoresist is homogeneously applied, and a window is opened on a part of the photoresist where the thick film positive electrode 120 is to be formed. Thereafter, the vanadium (V) layer 121 having about 17.5 nm film thickness, the gold (Au) layer 122 having about 1.5 μm film thickness, and the aluminum (Al) layer 123 having about 10 nm film thickness are sequentially deposited on the transmittive thin film positive electrode 110 to obtain films for the thick film positive electrode 120 in accordance with lift-off technology as in the step (4).

(5) Then, a heat treatment (sintering) for reducing a contact resistance between the n-type contact layer 104 and the negative electrode 140 as well as a contact resistance between the p-type contact layer 108 and the transmittive thin film positive electrode 110 is carried out. More specifically, a sample atmosphere is exhausted by a vacuum pump, O₂ gas is supplied to obtain 10 Pa pressure, an atmosphere temperature is adjusted to about 570° C. while keeping its condition, and the materials in process are heated for around four minutes.

Thereafter, the protective layer 130 made of SiO₂ is homogeneously formed on the uppermost layer exposed upwards, and one each window for forming a region through which the thick film positive electrode 120 or the negative electrode 140 is externally exposed so as to have substantially the same area as that of each of the electrodes is provided in accordance with wet etching through an application of a photoresist and a photolithographic step.

Furthermore, a reflection film of Al is deposited by evaporation on the back of the sapphire substrate.

As described above, the semiconductor light-emitting device 100 illustrated in FIG. 2 is thus formed.

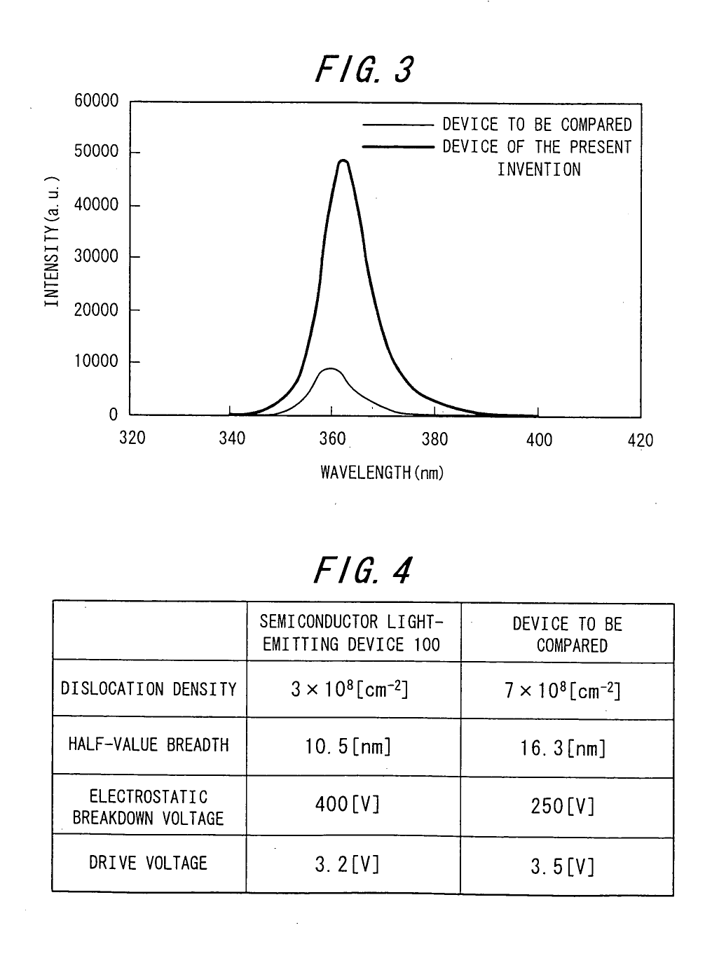

In FIG. 3, PL spectra (photoluminescence) of two semiconductor light-emitting devices (a product according to the invention of this application and a device to be compared) before laminating the multiple layer 105 are shown, while advantageous effects of the present invention in the above-described example 1 are specifically exemplified in FIG. 4. However, it is to be noted that no semiconductor layer 103 composed of the above-mentioned semiconductor layers A and B was laminated, and a film thickness of the n-type contact layer 104 was about 5 μm in the trial device to be compared. As to the other lamination structures, crystal growth conditions and the like, there was no difference between the semiconductor light-emitting device 100 and the device to be compared.

Moreover, ten-fold values of measurement values are indicated as to emission intensity of the device to be compared in a graphical representation of FIG. 3 with taking easy observation of the graph into consideration.

A peak wavelength of PL spectrum in the semiconductor layers 103 and 104 according to the invention of this application is within a range of from 362 nm to 363 nm, so that it results in a comparatively sharp and narrow contour wherein its half-value breadth is about 10.5 nm.

On the other hand, a wavelength of emission peak of the device to be compared which was fabricated in accordance with a well-known conventional technology ranges from 359 nm to 360 nm which is substantially an equal value to that of the above-described semiconductor layers 103 and 104, but its half-value breadth is about 16.3 nm. As a result, emission intensity in the peak wavelength exhibits only about 1/50 with respect to that of the semiconductor light-emitting device 100.

Moreover, when measured drive voltages of the respective light-emitting devices, a comparatively low value of about 3.2 V is obtained in the semiconductor light-emitting device 100, while it is a comparatively high value of 3.5 V in the device to be compared.

Furthermore, as a result of measuring electrostatic breakdown voltages upon the respective light-emitting devices, it is found that a comparatively high value of about 400 V was in the semiconductor light-emitting device 100, while it was a comparatively low value of about 250 V in the device to be compared.

Besides, a dislocation density in (10-10) plane of each n-type contact layer 104 which is fabricated under the same condition in the respective light-emitting devices is measured. As a result, it is found that a comparatively low dislocation density of 3×10⁸ cm⁻² was obtained in the n-type contact layer 104 of the semiconductor light-emitting device 100, while it was a comparatively high value of 7×10⁸ cm⁻² in the device to be compared.

From the results measured, it is found that a dislocation density of the n-type contact layer 104 is effectively suppressed due to actions of the semiconductor layer 103 composed of the semiconductor layers A and B in the semiconductor light-emitting device 100 fabricated in accordance with the present invention, so that a variety of good properties as mentioned above can be effectively assured.

### [The Other Modified Examples]

Embodiments of the present invention are not limited to those described above, but other modified examples as those exemplified hereunder are also applicable. Advantageous effects of the present invention can be obtained on the basis of functions of the invention even in such modifications and applications.

### (Modified Example 1)

For instance, a buffer layer is formed on a heterosubstrate (sapphire substrate), and then, the semiconductor layers A, B, and C according to the present invention are sequentially laminated in the above-described example 1. However, a substrate made of a bulk crystal of gallium nitride (GaN) may be used as a crystal growth substrate. In this case, no formation of a buffer layer is required, and a fear of appearance of stress exists scarcely, so that restrictions in fabrication of semiconductor light-emitting devices decrease, resulting in increase of further advantages in view of productivity and crystal quality thereof.

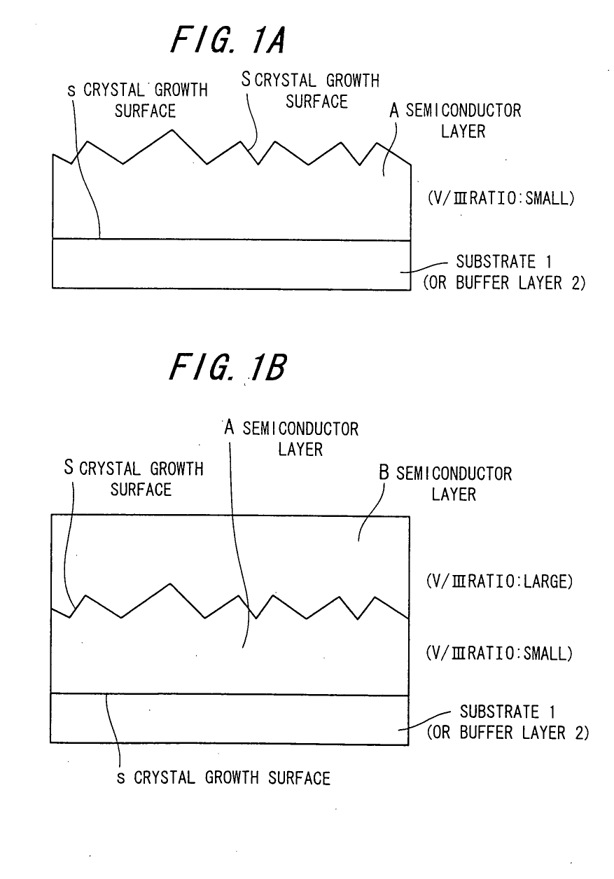

For instance, such a situation as mentioned above is relating to the description of advantages in the seventh means of the present invention. More specifically, when a III nitride-based compound semiconductor such as gallium nitride (GaN) is used as a crystal growth substrate (the substrate 1 in FIG. 1), differences in lattice constants or those in thermal expansion constants between the substrate and the semiconductor layers A, B, and C or light-emitting layers laminated thereafter can be suppressed in a small degree. Accordingly, a stress appearing in such device can be effectively suppressed according to the structure as described above, and hence, suppressing effects for occurrences of cracks, dislocations and the like are attained.

Heretofore, since a supplier who produces and sells bulk crystals of gallium nitride (GaN) had scarcely existed, a manner wherein such bulk crystal of gallium nitride is used as a crystal growth substrate has been also scarcely taken. In recent years, however, suppliers who produce and sell bulk crystals of gallium nitride come to appear. Therefore, a fabrication process wherein a substrate made of a bulk crystal of gallium nitride (GaN) is used as a crystal growth substrate (the substrate 1 in FIG. 1) becomes an industrially sufficiently practical manner nowadays.

III nitride-based compound semiconductors (the semiconductor layers B and C) obtained by the present invention are excellent as a semiconductor crystal material. Hence, the III nitride-based compound semiconductors fabricated in accordance with the present invention may be applied significantly usefully to all the semiconductor devices such as semiconductor light-emitting devices, semiconductor light-receiving devices, and semiconductor pressure sensors, for example, light-emitting diodes, semiconductor lasers and the like. Particularly, a role as a crystal growth substrate for electronic devices is widely expected.

It will be appreciated by those of ordinary skill in the art that the present invention can be embodied in other specific forms without departing from the spirit or essential characteristics thereof.

The presently disclosed embodiments are therefore considered in all respects to be illustrative and not restrictive. The scope of the invention is indicated by the appended claims rather than the foregoing description, and all changes that come within the meaning and range of equivalents thereof are intended to be embraced therein.

1. A process for the fabrication of a III nitride-based compound semiconductor, comprising:
a first crystal growth step for growing a semiconductor layer A made of a III nitride-based compound semiconductor on a crystal growth surface provided by a substrate or a buffer layer by supplying a III element material gas at a rate of a_{III} [μmol/min] per unit time and supplying a V element material gas at a rate of a_{V} [μmol/min] per unit time; and
a second crystal growth step for growing a semiconductor layer B made of a III nitride-based compound semiconductor on the semiconductor layer A by supplying a III element material gas at a rate of b_{III} [μmol/min] per unit time and supplying a V element material gas at a rate of b_{V} [μmol/min] per unit time;
wherein a ratio R_{A} (≡a_{V}/a_{III}) is lower than a ratio R_{B} (≡b_{V}/b_{III}), whereby a lateral crystal growth rate V_{LA} of the semiconductor layer A in the first crystal growth step is lower than a lateral crystal growth rate V_{LB} of the semiconductor layer B in the second crystal growth step.

2. The process for the fabrication of a III nitride-based compound semiconductor as defined in claim 1, wherein:
the ratio R_{A} and the ratio R_{B} satisfy a condition R_{A}<900<R_{B}.

3. The process for the fabrication of a III nitride-based compound semiconductor as defined in claim 1, wherein:
the ratio R_{A} satisfies a condition 100<R_{A}<800.

4. The process for the fabrication of a III nitride-based compound semiconductor as defined in claim 2, wherein:
the ratio R_{A} satisfies a condition 100<R_{A}<800.

5. The process for the fabrication of a III nitride-based compound semiconductor as defined in claim 1, wherein:
a crystal growth temperature T_{B} of the semiconductor layer B in the second crystal growth step is established at a value higher than a crystal growth temperature T_{A} of the semiconductor layer A in the first crystal growth step.

6. The process for the fabrication of a III nitride-based compound semiconductor as defined in claim 5, wherein:
the crystal growth temperature T_{A} and the crystal growth temperature T_{B} satisfy a condition T_{A} [° C.]≦1000 [° C.]≦T_{B} [° C.]

7. The process for the fabrication of a III nitride-based compound semiconductor as defined in claim 1, wherein:
a film thickness of the semiconductor layer A is 0.3 μm or more.

8. The process for the fabrication of a III nitride-based compound semiconductor as defined in claim 1, wherein:
a film thickness of the semiconductor layer A is 1 μm or less.

9. The process for the fabrication of a III nitride-based compound semiconductor as defined in claim 1, comprising further:
a third crystal growth step for growing a semiconductor layer C made of a III nitride-based compound semiconductor on the semiconductor layer B, wherein:
a ratio R_{C} (=c_{V}/c_{III}) of a feed rate c_{V} [μmol/min] per unit time of a V element material gas with respect to a feed rate c_{III} [μmol/min] per unit time of a III element material gas in the third crystal growth step satisfies a condition R_{A}<R_{C}≦R_{B}.

10. The process for the fabrication of a III nitride-based compound semiconductor as defined in claim 9, wherein:
the ratio R_{B} and the ratio R_{C} satisfy a condition R_{C}≦1200≦R_{B}.

11. A process for the fabrication of a III nitride-based compound semiconductor, comprising:
a first crystal growth step for growing a first layer of a III nitride-based compound semiconductor at a first lateral crystal growth rate; and
a second crystal growth step for growing second layer of a III nitride-based compound semiconductor on the first layer at a second lateral crystal growth rate which is lower than the first lateral crystal growth rate.

12. The process for the fabrication of a III nitride-based compound semiconductor as defined in claim 11, comprising further:
a third crystal growth step for growing a third layer of a III nitride-based compound semiconductor on the second layer at a third lateral crystal growth rate which is higher than the first lateral crystal growth rate, but which is equal to or lower than the second lateral crystal growth rate.

13. A process for the fabrication of a III nitride-based compound semiconductor, comprising:
a first crystal growth step for growing a first layer of a III nitride-based compound semiconductor having a convexoconcave surface on a substrate or a buffer layer, the convexoconcave surface being magnified in accordance with a convexoconcave surface of the substrate or the buffer layer; and
a second crystal growth step for growing a second layer of a III nitride-based compound semiconductor on the first layer.
